(19) United States
(12) Patent Application Publication
(10) Pub. No.: US 2005/0241580 A1
(43) Pub. Date: Nov. 3, 2005

(54) Method for depositing thin film and thin film deposition system having separate jet orifices for spraying purge gas

(75) Inventors: Hea Jin Park, Gyeonggi-Do (KR); Sung Min Na, Gyeonggi-Do (KR)

Correspondence Address: MARGER JOHNSON & MCCOLLOM, P.C., 210 SW MORRISON STREET, SUITE 400, PORTLAND, OR, 97204, US

(73) Assignee: JUSUNG ENGINEERING CO., LTD., Gwangju-Si (KR)

(21) Appl. No.: 11/119,313

(22) Filed: Apr. 28, 2005

(30) Foreign Application Priority Data
Apr. 30, 2004 (KR) 2004-0030692

(51) Int. Cl. C23C 16/00

(52) U.S. Cl. 118/715; 427/255.23

(57) ABSTRACT

Disclosed are thin film deposition system and method. The thin film deposition system includes a reaction chamber; at least one susceptor installed in the reaction chamber for mounting a substrate thereon; a first gas sprayer rotatably located above the susceptor; and at least one second gas sprayer installed above the first gas sprayer for spraying purge gas. The thin film deposition system increases the absorption rate of source gas onto the surface of the substrate, efficiently shortens the supply cycles of the gases to improve the productivity thereof, and improves the cleaning effect of the purge gas so that a thin film is stably deposited on the substrate.

The present invention claims the benefit of Korean Patent Application No. 2004-0030692 filed on Apr. 30, 2004, which is hereby incorporated by reference.

### BACKGROUND OF THE INVENTION

1. Field of Invention

The present invention relates to a thin film deposition system, and more particularly to a thin film deposition system having at least one first gas sprayer having a rotatable structure for spraying raw gas and reaction gas and second gas sprayers located above the first gas sprayer for spraying purge gas, and a method for depositing a thin film using the same, thereby improving deposition effect and productivity of the thin film.

2. Description of the Prior Art

As a substrate has a large diameter, it is difficult to deposit a thin film having a uniform thickness on the overall surface of the large-diameter substrate. Further, when a plurality of substrates are introduced into a single reaction chamber so that thin films are deposited on the substrates, it is difficult to form thin films having the same thickness on all the substrates. This is due to the fact that raw gas is not uniformly distributed in the reaction chamber. When plural substrates are introduced into one reaction chamber so that thin films are simultaneously deposited on the substrates, the thin film yield is increased, but the above problems are generated. Thereby, this proposal cannot be practically used.

The size of a semiconductor element is decreased due to the high integration of the semiconductor element, thereby decreasing the vertical dimensions of the semiconductor element. For example, there are a gate insulating film of a transistor and a dielectric film of a capacitor serving as a data memory unit of a DRAM. In order to successfully form these thin films having a small thickness of approximately 100 Å, instead of a conventional chemical method for depositing a thin film by simultaneously supplying raw materials for ingredients to a substrate, a method for depositing a thin film by alternately supplying raw materials to a substrate has been developed. In such a new method, since the deposition of the thin film is achieved only by the chemical reaction on the surface of the substrate, a thin film having a uniform thickness is grown on the substrate regardless of the unevenness of the surface of the substrate, and since the thickness of the deposited thin film is not proportional to the time taken to deposit the thin film on the substrate but is proportional to the number of supply cycles of the raw materials, it is possible to precisely control the thickness of the deposited thin film.

However, when the above method is substantially applied, process speed is greatly reduced due to the supply of the raw materials, the supply of purge gas, and an exhaust time. Accordingly, another approach for improving the productivity of the thin film has been required.

In order to solve the above problem, the present applicant invented a thin film deposition system having at least one rotatable gas sprayer (Korean Patent Application No. 10-2002-0060145).

Hereinafter, with reference to FIGS. 1A and 1B, a conventional thin film deposition system will be described in detail.

FIG. 1A is a sectional view of the conventional thin film deposition system, and FIG. 1B is a perspective view illustrating the deposition of thin films on wafers using the conventional thin film deposition system.

As shown in FIG. 1A, the conventional thin film deposition system comprises a reaction chamber 10 provided with a gas outlet 12 formed there through for exhausting internal gas to the outside of the reaction chamber 10, a support 20 horizontally installed such that the support 20 is rotatable about a central shaft of the reaction chamber 10, susceptors 30 placed on the upper surface of the support 20 for mounting wafers 20 thereon and rotated entering on the central shaft of the reaction chamber 10, and a first gas sprayer 40 located above the susceptors 30 for allowing raw gas for ingredients of thin films to be deposited on the wafers 2, a reaction gas for achieving deposition, and a gas present in the reaction chamber to contact the upper surfaces of the wafers 2, and spraying a purge gas for exhausting the gases after the reaction.

Four susceptors 30 are placed on the support 20, and the wafers 2 are respectively mounted on the corresponding susceptors 30. One or more through holes 21 are formed through the support 20 at portions, on which the susceptors 30 are not placed, such that the through holes 21 are spirally arranged around the susceptors 30, thereby allowing the gases to be exhausted to the outside of the reaction chamber 10 through the gas outlet 12. Further, the gases sprayed through the first gas sprayer 40 are exhausted to the outside of the reaction chamber 10 through the gas outlet 12 via a gap between the support 20 and the inner wall of the reaction chamber 10.

The first gas sprayer 40 includes a raw gas sprayer 42 for spraying the raw gas through raw gas jet orifices 43, a reaction gas sprayer 44 for spraying the reaction gas through reaction gas jet orifices 45, and a pair of purge gas sprayers 46 for spraying the purge gas through purge gas jet orifices 47. The raw gas sprayer 42 and the reaction gas sprayer 44 are connected at an angle of 180°, and the respective purge gas sprayers 46 and the raw and reaction gas sprayers 42 and 44 are connected to an angle of 180°.

As shown in FIG. 1B, the raw, reaction, and purge gas sprayers 42, 44, and 46 spray corresponding gases onto the upper surfaces of the wafers 2, and are rotated in the horizontal direction by the rotation of a rotary shaft 48.

After the raw gas is sprayed onto the upper surfaces of the wafers 2, particles of the raw gas, which are suspended in the air rather than placed on the upper surfaces of the wafers 2, are exhausted to the outside of the reaction chamber (10 with reference to FIG. 1A) by the purge gas. After the spray of the purge gas is completed, the reaction gas for depositing particles of the raw gas, which are placed on the upper surfaces of the wafers 2, on the wafers 2 is sprayed. Then, after the deposition of the particles of the raw gas is completed, the purge gas is sprayed again to exhaust the reaction gas to the outside of the reaction chamber. That is, the spray of the raw gas, the spray of the purge gas, the spray of the reaction gas, and the spray of the purge gas are sequentially repeated, and the above four steps form one cycle of the deposition of the thin film.

When the above-described conventional thin film deposition system is used, the raw, reaction, and purge gas sprayers 42, 44, and 46 spray the corresponding gases under the condition that the sprayers 42, 44, and 46 are rotated centering on the rotary shaft 48, thereby not vertically downwardly spraying the corresponding gases onto the upper surfaces of the wafers 2 but curvedly spraying the corresponding gases onto the upper surfaces of the wafers 2. That is, as shown in FIG. 1B, the gas spraying lines are curved. Accordingly, the raw gas sprayed towards the wafers 2 is not sprayed only to the upper surfaces of the wafers 2, but is diffused to the inner wall of the reaction chamber, thereby reducing spraying efficiency. Further, the sprayed raw gas contacts the reaction gas in the air before the raw gas reaches the upper surfaces of the wafers 2. Moreover, an eddy of air is generated in the reaction chamber 10 due to the rotations of the raw, reaction, and purge gas sprayers 42, 44, and 46. The above eddy of air accelerates the contact between the raw gas and the reaction gas in the air.

In the case that the raw gas and the reaction gas contact each other in the air, undesired chemical reaction between the raw gas and the reaction gas occurs in the air before the particles of the raw gas reach the wafers 2, thus being incapable of being normally deposited on the wafers.

Further, in the case that the conventional thin film deposition system is used, when the rotary shaft 48 is rotated once, a thin film deposition process is performed one time. Here, when the rotary shaft 48 is rotated at a high speed to shorten the process time, the probability of the contact between the raw gas and the reaction gas in the air is increased, thereby inhibiting improvement in the productivity of thin films.

### SUMMARY OF THE INVENTION

Therefore, the present invention has been made in view of the above problems, and it is an object of the present invention to provide a thin film deposition system, which increases the absorption rate of a raw gas onto surfaces of wafers, and efficiently shortens supply cycles of respective gases, thereby having improved productivity.

It is another object of the present invention to provide a thin film deposition system, which improves the cleaning effect of a purge gas so as to stably deposit a thin film on upper surfaces of wafers.

In accordance with one aspect of the present invention, the above and other objects can be accomplished by the provision of a thin film deposition system comprising: a reaction chamber; at least one susceptor installed in the reaction chamber for mounting a substrate thereon; a first gas sprayer rotatably located above the susceptor; and at least one accelerating means located at a position corresponding to the susceptor for vertically accelerating gases supplied from the first gas sprayer.

Preferably, the accelerating means may be a second gas sprayer.

Further, preferably, source gas and reaction gas may be supplied along a central shaft of the first gas sprayer; and the first gas sprayer may include at least one source gas sprayer extended towards the inner wall of the reaction chamber for spraying the source gas, and at least one reaction gas sprayer extended towards the inner wall of the reaction chamber for spraying the reaction gas.

Moreover, preferably, the second gas sprayer is installed above the first gas sprayer such that the second gas sprayer covers the susceptors.

In accordance with a further aspect of the present invention, there is provided a thin film deposition system comprising: a reaction chamber; at least one susceptor installed in the reaction chamber for mounting a substrate thereon; a first gas sprayer rotatably located above the susceptor; and at least one second gas sprayer installed above the first gas sprayer for spraying purge gas.

In accordance with another aspect of the present invention, there is provided a thin film deposition method comprising: preparing a thin film deposition system including a reaction chamber, at least one susceptor installed in the reaction chamber for mounting a substrate thereon, a first gas sprayer rotatably located above the susceptor, and at least one accelerating means located at a position corresponding to the susceptor for vertically accelerating gases supplied from the first gas sprayer; mounting the substrate on the susceptor in the reaction chamber; spraying source gas and reaction gas onto the substrate through the rotated first gas sprayer; and spraying purge gas onto the substrate through the accelerating means.

In accordance with yet another aspect of the present invention, there is provided a thin film deposition method comprising: preparing a thin film deposition system including a reaction chamber, at least one susceptor installed in the reaction chamber for mounting a substrate thereon, a first gas sprayer rotatably located above the susceptor, and at least one second gas sprayer installed above the first gas sprayer for spraying purge gas; mounting the substrate on the susceptor in the reaction chamber; spraying source gas and reaction gas onto the substrate through the rotated first gas sprayer; and spraying purge gas onto the substrate through the second gas sprayer.

The thin film deposition system comprises a reaction chamber; at least one susceptor installed in the reaction chamber for mounting an object, on which a thin film is deposited, thereon; a first gas located above the susceptor for spraying first and second gases onto the object; and at least one second gas sprayer installed above the first gas sprayer for spraying third gas onto the object.

The first gas sprayer is rotated centering on a vertical rotary shaft, and includes at least one source gas sprayer installed in the reaction chamber along the rotary shaft and extended towards the inner wall of the reaction chamber for spraying source gas serving as the first gas, and at least one reaction gas sprayer installed in the reaction chamber along the rotary shaft and extended towards the inner wall of the reaction chamber for spraying reaction gas serving as the second gas. Here, the source gas sprayer and the reaction gas sprayer meet at a right angle, and are alternately disposed.

The second gas sprayer has a size sufficient for covering objects, on which thin film are deposited, sprays purge gas serving as the third gas onto the object, and includes a plurality of jet orifices formed through the lower portions thereof such that the jet orifices are spaced from each other by the same interval and form a spiral or lattice shape.

The number of the susceptors in the reaction chamber is plural, and the number of the second gas sprayers is plural corresponding to the number of the susceptors such that the second gas sprayers are respectively located above the susceptors, or one second gas sprayer has a shape sufficient for simultaneously covering the susceptors.

Preferably, the gas spraying speed of the second gas sprayer may be higher than the gas spraying speed of the first gas sprayer.

The thin film deposition method of the present invention comprises: locating objects on susceptors in a reaction chamber, and spraying first and second gases onto the objects through the first gas sprayer and spraying third gas onto the objects through the second gas sprayer installed above the first gas sprayer. Here, the first gas is source gas, the second gas is reaction gas, and the third gas is purge gas.

Since the source gas and the reaction gas are simultaneously sprayed onto the objects, the thin film deposition method of the present invention shortens the supply cycle of the gases compared to a conventional thin film deposition method in which the source gas and the reaction gas are sequentially sprayed. Therefore, the thin film deposition method of the present invention shortens the thin film deposition cycle, thus improving the productivity of the thin film.

### BRIEF DESCRIPTION OF THE DRAWINGS

The above and other objects, features and other advantages of the present invention will be more clearly understood from the following detailed description taken in conjunction with the accompanying drawings, in which:

FIG. 1A is a sectional view of a conventional thin film deposition system;

FIG. 1B is a perspective view of the conventional thin film deposition system;

FIG. 2 is a sectional view illustrating the internal structure of a thin film deposition system in accordance with one embodiment of the present invention;

FIG. 3 is a perspective view of the thin film deposition system in accordance with one embodiment of the present invention;

FIG. 4 is a sectional view taken along the line A-A of FIG. 2; and

FIG. 5 is a sectional view of a second gas sprayer of a thin film deposition system in accordance with another embodiment of the present invention.

### DESCRIPTION OF THE PREFERRED EMBODIMENTS

Now, preferred embodiments of the present invention will be described in detail with reference to the annexed drawings.

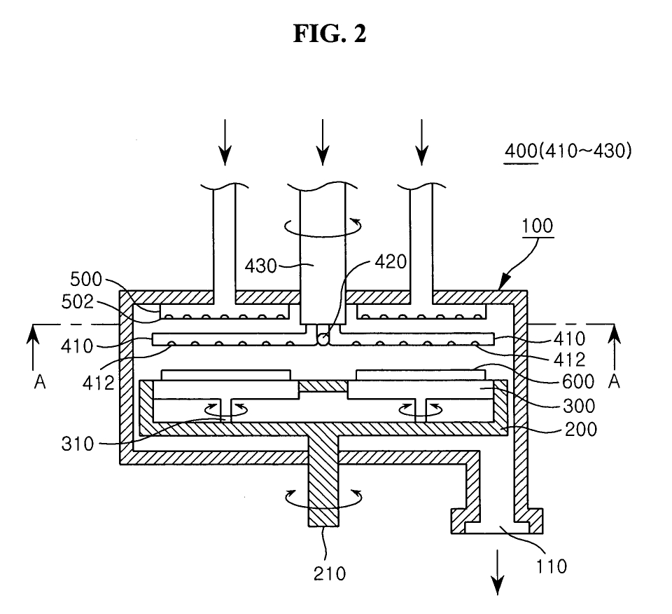

FIG. 2 is a sectional view illustrating the internal structure of a thin film deposition system in accordance with one embodiment of the present invention.

As shown in FIG. 2, the thin film deposition system in accordance with one embodiment of the present invention comprises a reaction chamber 100 provided with a gas outlet 110 formed there through for exhausting internal gas to the outside of the reaction chamber 100, a support 200 located in the reaction chamber 100 and provided with at least one susceptor 300 for mounting an object 600, for example, a semiconductor substrate, on which a thin film is deposited, thereon, a first gas sprayer 400 rotated centering on a vertical shaft for alternately spraying a process gas, such as a raw gas, and a reaction gas, onto the surface of the object 600 mounted on the susceptor 300, and second gas sprayers 500 installed above the first gas sprayer 400 for spraying a purge gas on the surface of the object 600 mounted on the susceptor 300 to clean the object 600 and the system.

The susceptor 300 is structured such that the susceptor 300 heats the object 600 mounted thereon to induce chemical reaction on the surface of the object 600. The above structure of the susceptor 300 is the same as that of the susceptor of the conventional thin film deposition system, and its detailed description will thus be omitted.

The first gas sprayer 400 includes a rotary shaft 430 serving as the center of rotation of the first gas sprayer 400 and including one end inserted into the reaction chamber 100 through the central portion of the upper part of the reaction chamber 100, and at least one raw gas sprayer 410 and at least one reaction gas sprayer 420 including ends inserted into the reaction chamber 100 through the rotary shaft 430 and the other ends longitudinally extended in the horizontal direction towards the inner wall of the reaction chamber 100 such that the raw and reaction gas sprayers 410 and 420 are separated from the upper surface of the susceptor 300 by a designated interval. In the case that two raw gas sprayers 410 and two reaction gas sprayers 420 are used, the two raw gas sprayers 410 and the two reaction gas sprayers 420 are alternately arranged such that the raw and reaction gas sprayers 410 and 420 meet at a right angle, and raw gas jet orifices 412 and reaction gas jet orifices 422 for spraying the raw and reaction gases there through are respectively formed through lower surfaces of the longitudinally extended portions of the raw and reaction gas sprayers 410 and 420.

When the raw gas sprayers 410 pass by the upper surfaces of the objects 600, the raw gas, which is supplied from the raw gas sprayers 410, is sprayed onto the surfaces of the objects 600 through the raw gas jet orifices 412, and when the reaction gas sprayers 420 pass by the upper surfaces of the objects 600, the reaction gas, which is supplied from the reaction gas sprayers 420, is sprayed onto the surfaces of the objects 600 through the reaction gas jet orifices 422. The rotation of the first gas sprayer 400 and the sprays of the raw and reaction gases onto the objects 600 by the first gas sprayer 400 are the same as those of the first gas sprayer of the conventional thin film deposition system, and its detailed description will thus be omitted.

In the conventional thin film deposition system, since the purge gas is sprayed after the raw gas is sprayed and the purge gas is sprayed again after the reaction gas is sprayed, the whole amounts of the sprayed raw and reaction gases are not transmitted to the wafers, and parts of the sprayed raw and reaction gases are diffused into the reaction chamber 100.

On the other hand, in the thin film deposition system of the present invention, since the purge gas is continuously sprayed onto the upper surfaces of the objects 600 through purge gas jet orifices 502 during the spraying of the raw or reaction gas onto the upper surfaces of the objects 600, the raw or reaction gas is pushed by the purge gas and is then transmitted to the surfaces of the objects 600. Accordingly, the amount of the raw or reaction gas diffused into the reaction chamber 100 is greatly decreased, thereby increasing efficiency in depositing thin films on the objects 600 and preventing the system from being contaminated by the raw or reaction gas diffused into the reaction chamber 100.

The second gas sprayers 500 of the thin film deposition system of the present invention serve to spray the purge gas at a speed higher than that of the raw or reaction gas, and increase a speed, at which the particles of the raw gas reach the surfaces of the objects 600, and a speed, at which the reaction gas contacts the particles of the raw gas reached the surfaces of the objects 600, thereby shortening the time taken to deposit thin films on the objects 600.

The support 200 is rotatable centering on a rotary shaft 210 formed in the vertical direction so that the raw gas and the reaction gas are uniformly disposed on all the objects 600 mounted on the susceptors 300, and each of the susceptors 300 is rotatable centering on a corresponding rotary shaft 310 formed in the vertical direction so that the raw gas and the reaction gas are uniformly disposed on the overall upper surface of the corresponding object 600.

In this embodiment, the support 200 and the susceptors 300 are rotatable. The rotatable structures of the support 200 and the susceptors 300 are the option for more uniformly depositing thin films on the objects 600. Accordingly, the support 200 and the susceptors 300 of the thin film deposition system of the present invention do not have the above rotatable structures, but may have fixed structures in which thin films are deposited on the objects 600 under the condition that the support 200 and the susceptors 300 are fixed.

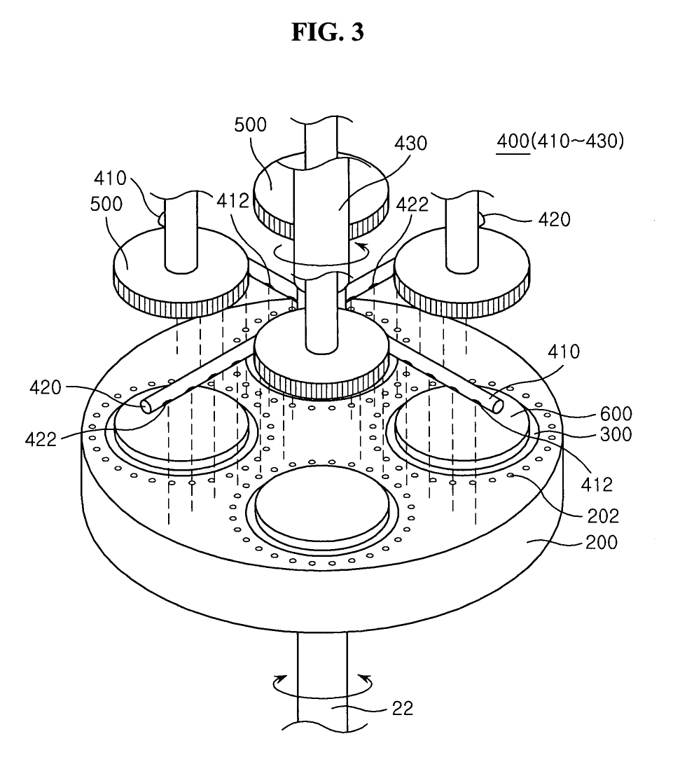

FIG. 3 is a perspective view of the thin film deposition system in accordance with one embodiment of the present invention.

As shown in FIG. 3, four susceptors 300, which are spirally arranged and meet at an angle of 90° centering on the vertical rotary shaft 210, are placed on the upper surface of the support 200. Although the number of the susceptors 300 is four in this embodiment, the number of the susceptors 300 may be variously modified according to various conditions, such as the size of the objects 600 and the size of the support 200.

One or more through holes 202 are formed through the support 200 at portions, on which the susceptors 300 are not placed, such that the through holes 202 are spirally arranged around the susceptors 300, thereby allowing the gases to be exhausted to the outside of the reaction chamber 100 through the gas outlet 110 (with reference to FIG. 2). Although the through hole 202 is formed through the support 200 in this embodiment, the support 200 may not include the through hole 202. In the case that the support 200 does not include the through hole 202, the support 200 is structured such that the gases in the reaction chamber 100 are exhausted to the outside through the gas outlet 110 through a gap between the support 200 and the inner wall of the reaction chamber 100.

The first gas sprayer 400 includes a pair of the raw gas sprayers 410, which are horizontally extended such that the raw gas sprayers 410 meet at an angle of 180°, a pair of the reaction gas sprayers 420, which are at a right angle to the raw gas sprayers 410 and are horizontally extended such that the reaction gas sprayers 420 meet at an angle of 180°, and the rotary shaft 430 connected to the raw gas sprayers 410 and the reaction gas sprayers 420 and serving as a rotary center of the first gas sprayer 400.

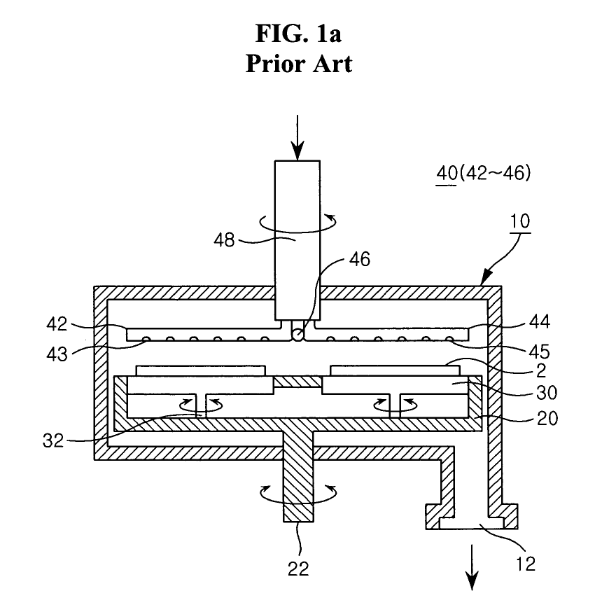

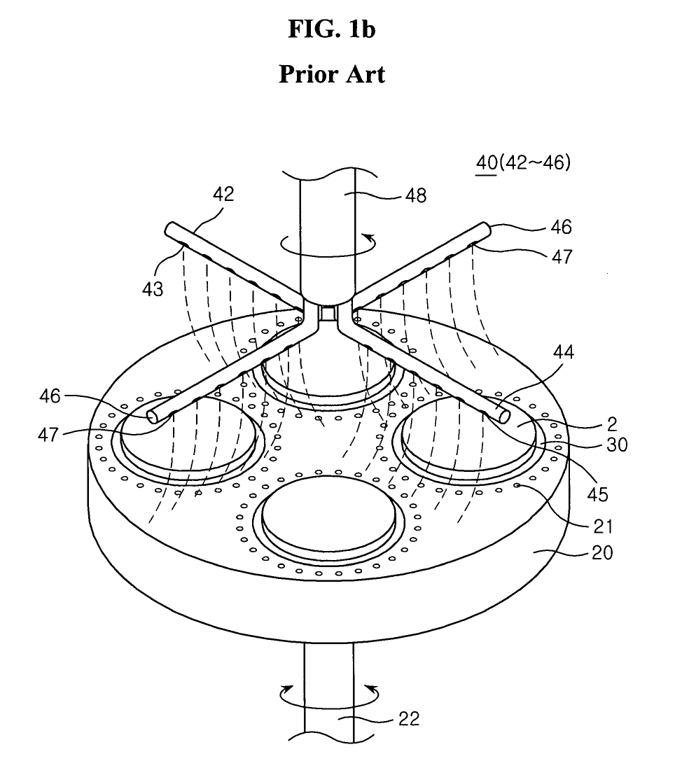

In the conventional thin film deposition system as shown in FIG. 1B, when the rotary shaft 46 is rotated once, the spray of the raw gas onto the upper surfaces of the wafers 2 and the spray of the reaction gas onto the upper surfaces of the wafers 2 are respectively performed one time, i.e., the thin film deposition process is performed one time. However, in the thin film deposition system of the present invention as shown in FIG. 3, when the rotary shaft 430 is rotated once, the spray of the raw gas onto the upper surfaces of the objects 600 and the spray of the reaction gas onto the upper surfaces of the objects 600 are respectively performed two times, i.e., the thin film deposition process is performed two times, thereby shortening the time taken to perform the thin film deposition process and improving the productivity of the thin film deposition system.

Although this embodiment employs two raw gas sprayers 410 and two reaction gas sprayers 420 such that the two raw gas sprayers 410 and the two reaction gas sprayers 420 are alternately arranged in a “+” shape, the numbers of the raw gas sprayers 410 and the reaction gas sprayers 420 are not limited thereto and may be various modified. Here, in the case that the numbers of the raw gas sprayers 410 and the reaction gas sprayers 420 are extremely larger, the raw gas may chemically react with the reaction gas before the raw gas reaches the objects 600, and in the case that the numbers of the raw gas sprayers 410 and the reaction gas sprayers 420 are extremely small, the cycle of the thin film deposition process is elongated, thus lowering the productivity of the thin film deposition system. Accordingly, preferably, the numbers of the raw gas sprayers 410 and the reaction gas sprayers 420 are properly determined by the spraying speeds of the raw and reaction gas, the rotational speed of the first gas sprayer 400, and the spraying speed of the purge gas.

Each of the second gas sprayers 500 is located above the corresponding susceptor 300, has a shape sufficient for covering the corresponding object 600 to uniformly spray the purge gas throughout the overall upper surface of the object 600 mounted on the upper surface of the susceptor 300, and includes jet orifices formed through the lower surface thereof and spaced from each other by a uniform interval for spraying the purge gas.

Generally, each of the objects 600 has a circular shape. Preferably, in order to increase the space utility of the inside of the thin film deposition system and the efficiency of heating the objects 600, each of the susceptors 300 has the same circular shape as that of the object 600. Further, preferably, in order to spray the purge gas only onto the regions of the objects 600 to efficiently use the purge gas, each of the second gas sprayers 500 has the same circular shape.

Accordingly, in the case that the thin film deposition system of the present invention is used, the purge gas is continuously sprayed from the second gas sprayers 500 when the raw gas and the reaction gas are sprayed from the raw gas sprayers 410 and the reaction gas sprayers 420, and vertically downwardly pushes the raw gas and the reaction gas. Thereby, although the rotary shaft 430 is rotated, the raw gas and the reaction gas are not diffused into the reaction chamber nor curved, but are directly sprayed onto the upper surfaces of the objects 600. Particularly, when the spraying speed of the purge gas is extremely high, the spraying lines of the raw gas and the reaction gas are close to a straight line as shown in FIG. 3.

When the raw gas and the reaction gas are directly sprayed onto the upper surfaces of the objects 600 as described above, the raw gas and the reaction gas do not generate chemical reaction before the raw gas and the reaction gas contact the objects 600, thereby improving the efficiency in depositing a thin film.

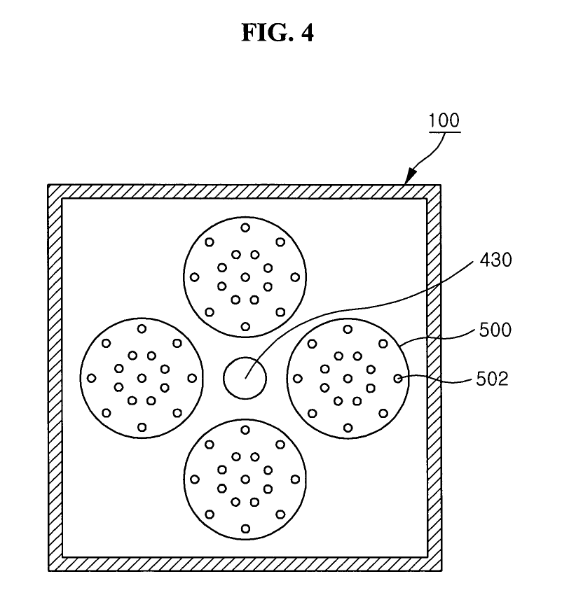

FIG. 4 is a sectional view taken along the line A-A of FIG. 2.

As shown in FIG. 4, each of the second gas sprayers 500 for spraying the purge gas of the thin film deposition system of the present invention has the same shape as that of each of the objects 600, and is located just above the corresponding object 600.

The above structures of the second gas sprayers 500 cause the purge gas to be sprayed only onto the upper surfaces of the objects 600 in order to prevent the loss of the purge gas. The number, the shape, and the location of the second gas sprayers 500 are not limited thereto, but may be variously modified.

Particularly, in the case that the support 200 is rotated when the purge gas is sprayed, the location of the second gas sprayers 500 vertically above the objects 600 is not important. In this case, preferably, the shape and the location of the second gas sprayers 500 are changed so that the purge gas is uniformly sprayed onto the upper surfaces of the objects 600 rotated centering on the vertical rotary shaft 210 of the support 200.

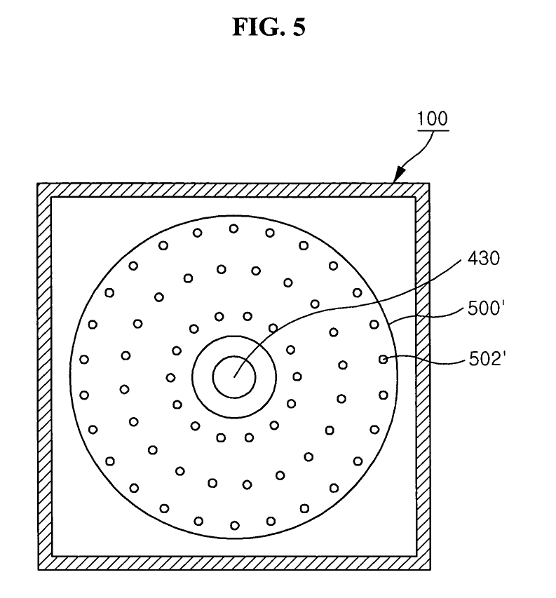

FIG. 5 is a sectional view of a second gas sprayer of a thin film deposition system in accordance with another embodiment of the present invention.

The second gas sprayer 500′ of the thin film deposition system of this embodiment has a size sufficient for covering the all of the upper surfaces of the objects 600 by the rotation of the support 200.

When the second gas sprayer 500′ has a ring shape as shown in FIG. 5, the purge gas is uniformly sprayed onto the upper surfaces of all of the objects 600 regardless of the locations of the objects 600.

As apparent from the above description, the present invention provides a thin film deposition method, in which reaction gas and source gas are simultaneously sprayed to shorten the supply cycle of the gases, thereby improving the productivity.

Further, the present invention provides a thin film deposition system, which improves the cleaning effect of purge gas so that thin films are stably deposited on upper surfaces of wafers, increases the absorption rate of raw gas onto the surfaces of the wafers, and prevents the absorption of the raw gas onto the inner surface of a reaction chamber so that the management of the system is easy.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A thin film deposition system comprising:
a reaction chamber;
at least one susceptor installed in the reaction chamber for mounting a substrate thereon;
a first gas sprayer rotatably located above the susceptor; and
at least one accelerating means located at a position corresponding to the susceptor for vertically accelerating gases supplied from the first gas sprayer.

2. The thin film deposition system as set forth in claim 1, wherein the accelerating means is a second gas sprayer.

3. The thin film deposition system as set forth in claim 1, wherein:
source gas and reaction gas are supplied along a central shaft of the first gas sprayer; and
the first gas sprayer includes at least one source gas sprayer extended towards the inner wall of the reaction chamber for spraying the source gas, and at least one reaction gas sprayer extended towards the inner wall of the reaction chamber for spraying the reaction gas.

4. The thin film deposition system as set forth in claim 1, wherein a plurality of the source gas sprayers and a plurality of the reaction gas sprayers are alternately installed parallel with the substrates.

5. The thin film deposition system as set forth in claim 4, wherein the source gas sprayers and the reaction gas sprayers meet at a right angle, and a plurality of jet orifices are formed through lower portions of the source and reaction gas sprayers.

6. The thin film deposition system as set forth in claim 2, further comprising:
a rotary shaft; and
a support, on which a plurality of the susceptors are installed, connected to the rotary shaft and rotated centering on the rotary shaft.

7. The thin film deposition system as set forth in claim 6, wherein the second gas sprayer is installed above the first gas sprayer such that the second gas sprayer covers the susceptors.

8. The thin film deposition system as set forth in claim 6, wherein at least one through hole is formed through a portion of the support adjacent to the susceptors.

9. The thin film deposition system as set forth in claim 2, wherein a plurality of the second gas sprayers have the same shapes as those of the susceptors and sizes sufficient for respectively covering the substrates, are located at positions corresponding to the susceptors, and spray purge gas.

10. The thin film deposition system as set forth in claim 2, wherein second jet orifices are formed through the lower portion of each of the second gas sprayers such that the second jet orifices are spaced from each other by the same interval and form a spiral or lattice shape.

11. The thin film deposition system as set forth in claim 2, wherein the number of the susceptors in the reaction chamber is plural, and the number of the second gas sprayers is plural such that the second gas sprayers respectively correspond to the susceptors.

12. The thin film deposition system as set forth in claim 2, wherein the gas spraying speed of the second gas sprayer is higher than the gas spraying speed of the first gas sprayer.

13. The thin film deposition system as set forth in claim 1, further comprising a gas outlet for exhausting the gases in the reaction chamber to the outside.

14. A thin film deposition system comprising:
a reaction chamber;
at least one susceptor installed in the reaction chamber for mounting a substrate thereon;
a first gas sprayer rotatably located above the susceptor; and
at least one second gas sprayer installed above the first gas sprayer for spraying purge gas.

15. The thin film deposition system as set forth in claim 14, wherein:
source gas and reaction gas are supplied along a central shaft of the first gas sprayer; and
the first gas sprayer includes at least one source gas sprayer extended towards the inner wall of the reaction chamber for spraying the source gas, and at least one reaction gas sprayer extended towards the inner wall of the reaction chamber for spraying the reaction gas.

16. A thin film deposition method comprising:
preparing a thin film deposition system including a reaction chamber, at least one susceptor installed in the reaction chamber for mounting a substrate thereon, a first gas sprayer rotatably located above the susceptor, and at least one accelerating means located at a position corresponding to the susceptor for vertically accelerating gases supplied from the first gas sprayer;
mounting the substrate on the susceptor in the reaction chamber;
spraying source gas and reaction gas onto the substrate through the rotated first gas sprayer; and
spraying purge gas onto the substrate through the accelerating means.

17. The thin film deposition method as set forth in claim 16, wherein the source gas, the reaction gas, and the purge gas are simultaneously sprayed.

18. A thin film deposition method comprising:
preparing a thin film deposition system including a reaction chamber, at least one susceptor installed in the reaction chamber for mounting a substrate thereon, a first gas sprayer rotatably located above the susceptor, and at least one second gas sprayer installed above the first gas sprayer for spraying purge gas;
mounting the substrate on the susceptor in the reaction chamber;
spraying source gas and reaction gas onto the substrate through the rotated first gas sprayer; and
spraying purge gas onto the substrate through the second gas sprayer.
